(19) United States
(12) Patent Application Publication
(10) Pub. No.: US 2025/0151579 A1
(43) Pub. Date: May 8, 2025

(54) DISPLAY DEVICE

(71) Applicant: Samsung Display Co., LTD., Yongin-si (KR)

(72) Inventors: Hyo Chang KIM, Yongin-si (KR); Byeong Kyu PARK, Yongin-si (KR); Young Eun OH, Yongin-si (KR); Han Sun RYOU, Yongin-si (KR)

(21) Appl. No.: 18/740,336

(22) Filed: Jun. 11, 2024

(30) Foreign Application Priority Data
Nov. 3, 2023 (KR) 10-2023-0151019

(51) Int. Cl. H10K 59/80; H10K 59/40; H10K 77/10; H10K 102/00

(52) U.S. Cl. CPC H10K 59/873; H10K 59/8791; H10K 77/111; H10K 59/40; H10K 2102/311; H10K 2102/351

(57) ABSTRACT

The display device includes a display panel, and a protective member on a surface of the display panel, wherein the protective member includes a base layer, a primer layer on the base layer and including fillers, and an antistatic layer on the primer layer, wherein a thickness of the antistatic layer is smaller than a particle size of the fillers.

### CROSS-REFERENCE TO RELATED APPLICATION

The present application claims priority to and the benefit of Korean Patent Application No. 10-2023-0151019, filed on Nov. 3, 2023, in the Korean Intellectual Property Office, the entire content of which is incorporated herein by reference.

### BACKGROUND

### 1. Field

Embodiments of the present disclosure described herein are related to a display device.

### 2. Description of the Related Art

Electronic devices, such as smartphones, tablet PCs, digital cameras, laptop computers, navigation systems, and/or smart televisions, that provide images to users, may each include a display device for displaying images.

Recently, foldable display devices have been drawing greater attention. Because foldable display devices are portable and can have a relatively wide screen, they have advantages for utilization in both smartphones and tablet PCs.

Members that form (or provide) the exterior or interior of a foldable display device may include or require flexibility and durability to enable folding and unfolding operations.

### SUMMARY

Aspects according to one or more embodiments of the present disclosure are directed toward a display device in which the defects and surface quality of a protective member that protects a display panel from under the display panel can be improved.

Aspects according to one or more embodiments of the present disclosure are directed toward a display device in which the defects and surface quality of a protective member attached to a lower surface of the display panel can be improved by reducing the surface friction coefficient of the protective member.

However, aspects of the present disclosure are not restricted to the one set forth herein. The above and other aspects of the present disclosure will become more apparent to one of ordinary skill in the art to which the present disclosure pertains by referencing the detailed description of the present disclosure given herein.

According to one or more embodiments of the present disclosure, a display device includes a display panel, and a protective member arranged on a surface of the display panel, wherein the protective member includes a base layer, a primer layer arranged on the base layer and including fillers, and an antistatic layer arranged on the primer layer, wherein a thickness of the antistatic layer is smaller than a particle size of the fillers.

In one or more embodiments, the base layer is arranged closer to the display panel than to the antistatic layer is to the display panel.

In one or more embodiments, the base layer includes polyethylene terephthalate (PET) and has a heat shrinkage rate of about 0.2% or less when exposed to a temperature of about 150° C. for about 30 minutes.

In one or more embodiments, a thickness of the base layer is about 10 μm to about 100 μm.

In one or more embodiments, the particle size of the fillers is about 0.01 μm to 2 μm.

In one or more embodiments, the content (e.g., amount) of the fillers is about 0.01% to 80% by weight based on total weight of 100% of the primer layer.

In one or more embodiments, a thickness of the primer layer is about 10 nm to about 300 nm.

In one or more embodiments, the thickness of the antistatic layer is about 10 nm to about 1000 nm.

In one or more embodiments, the sum of the thickness of the primer layer and the thickness of the antistatic layer is smaller than the particle size of the fillers.

In one or more embodiments, a surface friction coefficient of the protective member is about 0.320 to about 0.451.

In one or more embodiments, the display device further includes a polarizing member arranged on the display panel, a shock absorbing layer arranged on the polarizing member, a cover window arranged on the shock absorbing layer, and bonding members arranged between the display panel and the polarizing member, between the polarizing member and the shock absorbing layer, and between the shock absorbing layer and the cover window.

In one or more embodiments, the display device further includes a cushion layer arranged on a surface of the protective member, wherein the cushion layer faces the antistatic layer.

According to one or more embodiments of the present disclosure, a display device includes a display panel, and a protective member arranged on a surface of the display panel, wherein the protective member includes a base layer including fillers, a primer layer arranged on the base layer, and an antistatic layer arranged on the primer layer and having protrusions, wherein the protrusions overlap the fillers.

In one or more embodiments, a ratio of an area occupied by the fillers to a total area of the protective member is about 1.5% to about 2%.

In one or more embodiments, a surface friction coefficient of the protective member is about 0.320 to about 0.451.

In one or more embodiments, a thickness of the base layer is about 10 micrometer (μm) to about 100 μm.

In one or more embodiments, the content (e.g., amount) of the fillers is about 0.01% to 80% by weight based on total weight of 100% of the base layer.

In one or more embodiments, a thickness of the primer layer is about 10 nanometer (nm) to about 300 nm.

In one or more embodiments, a thickness of the antistatic layer is about 10 nm to about 1000 nm.

According to one or more embodiments of the present disclosure, a display device includes a display panel, a polarizing member arranged on a surface of the display panel, a shock absorbing layer arranged on the polarizing member, a cover window arranged on the shock absorbing layer, and a protective member arranged on the other surface (e.g., opposite surface) of the display panel, wherein the protective member includes a base layer, a primer layer arranged on the base layer and including fillers, and an antistatic layer arranged on the primer layer, wherein the sum of a thickness of the primer layer and a thickness of the antistatic layer is smaller than a particle size of the fillers.

However, the effects and/or aspects of the present disclosure are not restricted to the one set forth herein. The above and other effects and/or aspects of the present disclosure will become more apparent to one of ordinary skill in the art to which the present disclosure pertains by referencing the claims.

### BRIEF DESCRIPTION OF THE DRAWINGS

These and/or other aspects will become apparent and more readily appreciated from the following description of the embodiments, taken in conjunction with the accompanying drawings in which:

FIG. 1 is a perspective view illustrating an unfolded state of a display device according to one or more embodiments;

FIG. 2 is a perspective view illustrating a folded state of the display device according to one or more embodiments;

FIG. 3 is a perspective view illustrating an unfolded state of a display device according to one or more embodiments;

FIG. 4 is a perspective view illustrating a folded state of the display device according to the embodiment of FIG. 3;

FIG. 5 is a cross-sectional view of a display device in an unfolded state according to one or more embodiments;

FIG. 6 is a schematic cross-sectional view of a display panel according to one or more embodiments;

FIG. 7 is a schematic cross-sectional view of a protective member according to one or more embodiments;

FIG. 8 is a graph illustrating the transmittance of heat-resistant PET with respect to wavelength;

FIG. 9 is a schematic plan view of the protective member according to one or more embodiments;

FIG. 10 is a schematic cross-sectional view of a portion of a display device according to one or more embodiments;

FIG. 11 is a schematic cross-sectional view of a protective member according to one or more embodiments;

FIG. 12 is a schematic plan view of the protective member according to the embodiment of FIG. 11;

FIG. 13 is a schematic cross-sectional view of a portion of a display device according to one or more embodiments;

FIG. 14 is a graph illustrating the surface friction coefficients of protective member samples of Comparative Example and Example according to Experimental Example 1;

FIG. 15 is a graph illustrating the Kc values of protective member samples according to Experimental Example 2; and

FIG. 16 is a table showing Optimap images of the protective member samples according to Experimental Example 2.

### DETAILED DESCRIPTION

The present disclosure will now be described more fully hereinafter with reference to the accompanying drawings, in which embodiments of the present disclosure are shown. This present disclosure may, however, be embodied in different forms and should not be construed as limited to the embodiments set forth herein. Rather, these embodiments are provided so that this disclosure will be thorough and complete, and will fully convey the scope of the present disclosure to those skilled in the art.

It will also be understood that when a layer is referred to as being “on” another layer or substrate, it can be directly on the other layer or substrate, or intervening layers may also be present. The same reference numbers indicate the same components throughout the specification.

It will be understood that, although the terms “first,” “second,” and/or the like may be utilized herein to describe one or more suitable elements, these elements should not be limited by these terms. These terms are only utilized to distinguish one element from another element. For instance, a first element discussed herein could be termed a second element without departing from the teachings of the present disclosure. Similarly, the second element could also be termed the first element.

Each of the features of the one or more suitable embodiments of the present disclosure may be combined or combined with each other, in part or in whole, and technically one or more suitable interlocking and driving are possible. Each embodiment may be implemented independently of each other or may be implemented together in an association.

Throughout the disclosure, the expression “at least one of a, b or c” indicates only a, only b, only c, both (e.g., simultaneously) a and b, both (e.g., simultaneously) a and c, both (e.g., simultaneously) b and c, all of a, b, and c, or variations thereof.

In the present specification, “including A or B”, “A and/or B”, etc., represents A or B, or A and B.

As used herein, the term “substantially,” “about,” and similar terms are used as terms of approximation and not as terms of degree, and are intended to account for the inherent deviations in measured or calculated values that would be recognized by those of ordinary skill in the art. “Substantially” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “substantially” may mean within one or more standard deviations, or within ±30%, 20%, 10%, 5% of the stated value.

Also, any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

Further, the use of “may” when describing embodiments of the present disclosure refers to “one or more embodiments of the present disclosure.”

As used herein, the singular forms “a,” “an” and “the” are intended to include the plural forms as well, unless the context clearly indicates otherwise.

In present disclosure, “not including a or any ‘component’” “excluding a or any ‘component’”, “‘component’-free”, and/or the like refers to that the “component” not being added, selected or utilized as a component in the composition/structure, but the “component” of less than a suitable amount may still be included due to other impurities and/or external factors.

Hereinafter, one or more embodiments will be described with reference to the accompanying drawings.

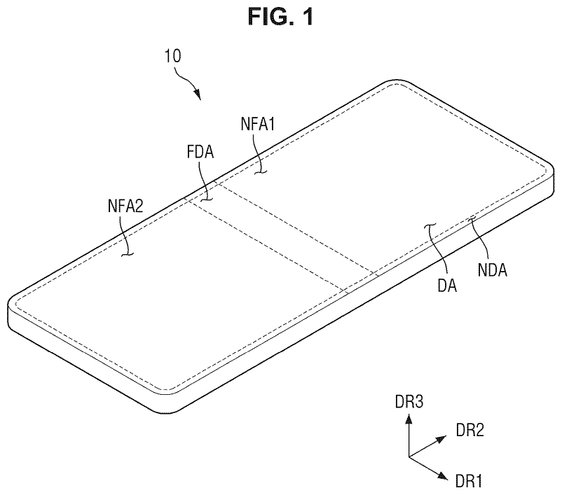

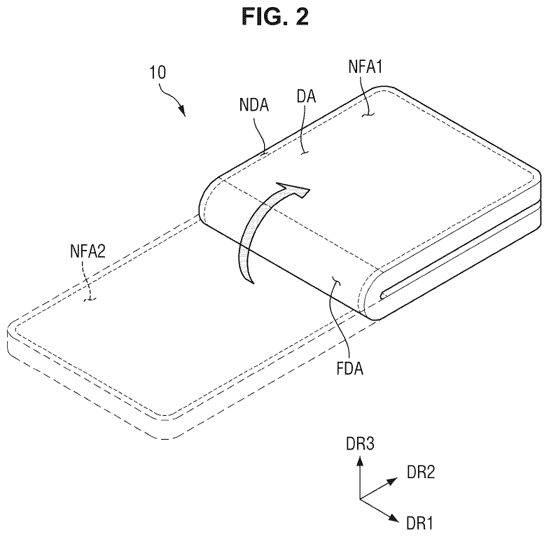

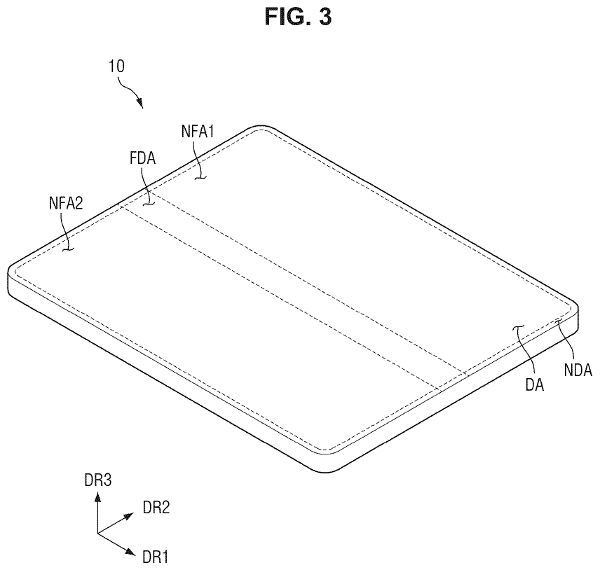

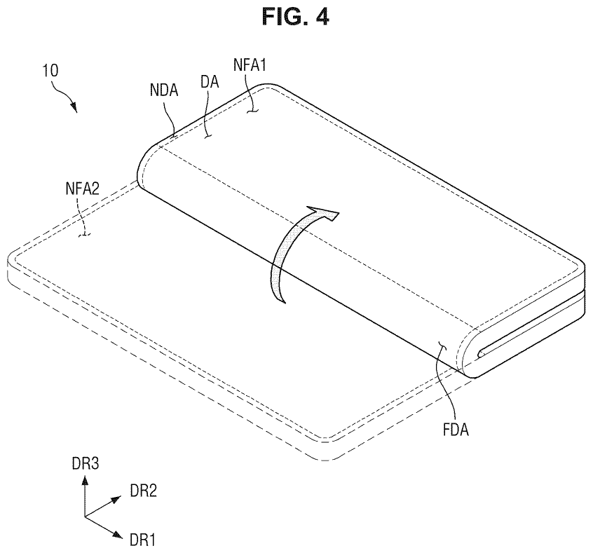

FIG. 1 is a perspective view illustrating an unfolded state of a display device 10 according to one or more embodiments. FIG. 2 is a perspective view illustrating a folded state of the display device 10 according to one or more embodiments. FIG. 3 is a perspective view illustrating an unfolded state of a display device 10 according to one or more embodiments. FIG. 4 is a perspective view illustrating a folded state of the display device 10 according to one or more embodiments of FIG. 3.

Referring to FIG. 1, the display device 10 according to the embodiment may be a foldable display device. A case where the display device 10 is applied to a smartphone will be described herein, but the present disclosure is not limited to this case. For example, the display device 10 according to one or more embodiments of the present specification can be applied not only to smartphones, but also to mobile phones, tablet PCs, personal digital assistants (PDAs), portable multimedia players (PMPs), televisions, game consoles, wristwatch-type or kind electronic devices, head mounted displays, monitors of PCs, laptop computers, car navigation systems, car dashboards, digital cameras, camcorders, outdoor billboards, electronic display boards, medical devices, examination devices, one or more suitable home appliances such as refrigerators and washing machines, or Internet of things (IoT) devices. Specific embodiments will be described with reference to the accompanying drawings.

In FIGS. 1 and 2, a first direction DR1 may be a direction parallel to a side of the display device 10 when seen in a plan view, for example, may be a horizontal direction (e.g., an x-axis direction) of the display device 10. A second direction DR2 may be a direction parallel to another side in contact with the above side of the display device 10 when seen in a plan view, for example, may be a vertical direction (e.g., a y-axis direction) of the display device 10. A third direction DR3 may be a thickness direction of the display device 10.

In one or more embodiments, the display device 10 may be rectangular in a plan view. The display device 10 may be shaped like a rectangle with right-angled corners or a rectangle with rounded corners in a plan view. The display device 10 may include two short sides extending in the first direction DR1 and two long sides extending in the second direction DR2 in a plan view.

The display device 10 includes a display area DA and a non-display area NDA. The shape of the display area DA may correspond to the shape of the display device 10 in a plan view. For example, when the display device 10 is rectangular in a plan view, the display area DA may also be rectangular.

The display area DA may include a plurality of pixels to display an image. The pixels may be arranged in a matrix direction. Each of the pixels may be shaped like a rectangle, a rhombus, or a square in a plan view. However, the present disclosure is not limited thereto. For example, each of the pixels may also be shaped like a quadrilateral other than a rectangle, a rhombus or a square, a polygon other than a quadrilateral, a circle, or an oval in a plan view.

The non-display area NDA may not display an image because it does not include pixels. The non-display area NDA may be arranged around the display area DA. The non-display area NDA may surround the display area DA as illustrated in FIGS. 1 and 2. However, the present disclosure is not limited thereto. The display area DA may also be partially surrounded by the non-display area NDA.

In one or more embodiments, the display device 10 may maintain both (e.g., simultaneously) the folded state and the unfolded state. The display device 10 may be folded in an in-folding manner in which the display area DA is arranged inside as illustrated in FIG. 2. When the display device 10 is folded in the in-folding manner, portions of an upper surface of the display device 10 may face each other. In one or more embodiments, the display device 10 may be folded in an out-folding manner in which the display area DA is arranged outside. When the display device 10 is folded in the out-folding manner, portions of a lower surface of the display device 10 may face each other.

In one or more embodiments, the display device 10 may be a foldable device. As utilized herein, the term “foldable device” is utilized to refer to devices that can be folded, including not only a folded device but also a device that can have both (e.g., simultaneously) the folded state and the unfolded state. In one or more embodiments, folding typically includes folding at an angle of about 180 degrees. However, the present disclosure is not limited thereto, and folding at an angle of more than or less than about 180 degrees, such as folding at an angle of about 90 to less than about 180 degrees or an angle of about 120 to less than about 180 degrees may also be understood as folding. Furthermore, even an incompletely folded state may also be referred to as the folded state if it is not the unfolded state. For example, even a folded state at an angle of about 90 degrees or less may be expressed as the folded state to distinguish it from the unfolded state as long as a maximum folding angle is about 90 degrees or more. The radius of curvature at the time of folding may be, but is not limited to, about 5 millimeters (mm) or less, about 1 mm to 2 mm or about 1.5 mm.

In one or more embodiments, the display device 10 may include a folding area FDA, a first non-folding area NFA1, and a second non-folding area NFA2. The folding area FDA may be an area in which the display device 10 is folded, and the first non-folding area NFA1 and the second non-folding area NFA2 may be areas in which the display device 10 is not folded.

The first non-folding area NFA1 may be arranged on a side, e.g., an upper side of the folding area FDA. The second non-folding area NFA2 may be arranged on the other side, e.g., a lower side of the folding area FDA. The folding area FDA may be an area bent with a set or predetermined curvature.

In one or more embodiments, the folding area FDA of the display device 10 may be set at a specific position. In the display device 10, one folding area FDA or two or more folding areas FDA may be set at a specific position. In one or more embodiments, the folding area FDA may not be limited to a specific position in the display device 10 but may be set in one or more suitable areas.

In one or more embodiments, the display device 10 may be folded in the second direction DR2. As a result, a length of the display device 10 in the second direction DR2 may be reduced to about half. Therefore, a user can easily carry the display device 10.

In one or more embodiments, the direction in which the display device 10 is folded is not limited to the second direction DR2. For example, the display device 10 may also be folded in the first direction DR1. In this case, the length of the display device 10 in the first direction DR1 may be reduced to about half.

In FIGS. 1 and 2, each of the display area DA and the non-display area NDA overlaps the folding area FDA, the first non-folding area NFA1, and the second non-folding area NFA2. However, the present disclosure is not limited thereto. For example, each of the display area DA and the non-display area NDA may overlap at least one of the folding area FDA, the first non-folding area NFA1, or the second non-folding area NFA2.

Referring to FIGS. 3 and 4, in the display device 10 according to one or more embodiments, a first direction DR1 may be a direction parallel to a side of the display device 10 when seen in a plan view, for example, the first direction DR1 may be a vertical direction (e.g., a y-axis direction) of the display device 10. A second direction DR2 may be a direction parallel to another side in contact with the above side of the display device 10 when seen in a plan view, for example, the second direction DR2 may be a horizontal direction (e.g., an x-axis direction) of the display device 10. A third direction DR3 may be a thickness direction of the display device 10. The display device 10 may include two long sides extending in the first direction DR1 and two short sides extending in the second direction DR2 when seen in a plan view.

In the current embodiment, the display device 10 may be folded in an in-folding manner in which a display area DA is arranged inside as illustrated in FIG. 4 or may be folded in an out-folding manner in which the display area DA is arranged outside. The display device 10 may include a folding area FDA, a first non-folding area NFA1, and a second non-folding area NFA2. The folding area FDA may be an area bent with a set or predetermined curvature. The display device 10 may be folded in the second direction DR2. As a result, a length of the display device 10 in the second direction DR2 may be reduced to about half. Therefore, a user can easily carry the display device 10.

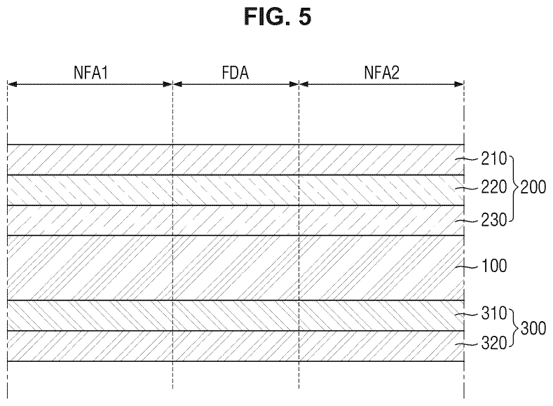

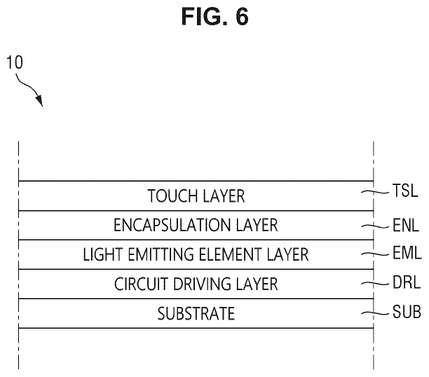

FIG. 5 is a cross-sectional view of a display device 10 in an unfolded state according to one or more embodiments. FIG. 6 is a schematic cross-sectional view of a display panel 100 according to one or more embodiments.

Referring to FIG. 5, the display device 10 may include the display panel 100, a front stacked structure 200 stacked in front of the display panel 100, and a rear stacked structure 300 stacked behind the display panel 100. Here, “in front of” the display panel 100 refers to a direction in which the display panel 100 displays a screen, and “behind” the display panel 100 refers to a direction opposite to the front (e.g., opposite to the direction in which the display panel 100 display the screen). A surface of the display panel 100 is located at the front, and the other surface of the display panel 100 is located at the rear (or at behind the display panel 100).

The display panel 100 is a panel that displays a screen or an image. Examples of the display panel 100 may include self-luminous display panels such as an organic light emitting display panel, an inorganic electroluminescent (EL) display panel, a quantum dot light emitting display panel (QED), a micro-light emitting diode (LED) display panel, a nano-LED display panel, a plasma display panel (PDP), a field emission display (FED) panel and a cathode ray tube (CRT) display panel as well as light-receiving display panels such as a liquid crystal display (LCD) panel and an electrophoretic display (EPD) panel. An organic light emitting display panel will be described herein as an example of the display panel 100. Unless a special distinction is desired or required, the organic light emitting display panel applied to one or more embodiments will be simply shortened to the display panel 100. However, the embodiments are not limited to the organic light emitting display panel, and other display panels listed above or suitable in the art can also be applied within the scope sharing the technical spirit.

The display panel 100 may further include a touch member. The touch member may be provided as a separate panel or film from the display panel 100 and attached onto the display panel 100. However, the touch member may also be provided in the form of a touch layer inside the display panel 100. In the following embodiments, a case where the touch member is provided inside the display panel 100 and included in the display panel 100 will be described, but the present disclosure is not limited thereto.

Referring to FIG. 6, the display panel 100 may include a substrate SUB, a circuit driving layer DRL on the substrate SUB, a light emitting element layer EML on the circuit driving layer DRL, an encapsulation layer ENL on the light emitting element layer EML, and a touch layer TSL on the encapsulation layer ENL.

The substrate SUB may be a flexible substrate including a flexible polymer material such as polyimide. Accordingly, the display panel 100 can be curved, bent, folded, or rolled. In one or more embodiments, the substrate SUB may include a plurality of sub-substrates overlapping each other in the thickness direction with a barrier layer interposed between them. In this case, each of the sub-substrates may be a flexible substrate.

The circuit driving layer DRL may be arranged on the substrate SUB. The circuit driving layer DRL may include a circuit that drives the light emitting element layer EML of each pixel. The circuit driving layer DRL may include a plurality of thin-film transistors.

The light emitting element layer EML may be arranged on the circuit driving layer DRL. The light emitting element layer EML may include an organic light emitting layer. The light emitting element layer EML may be configured to emit light at one or more suitable luminance levels according to a driving signal received from the circuit driving layer DRL.

The encapsulation layer ENL may be arranged on the light emitting element layer EML. The encapsulation layer ENL may include an inorganic layer or a stacked layer of an inorganic layer and an organic layer.

The touch layer TSL may be arranged on the encapsulation layer ENL. The touch layer TSL is a layer that detects touch input and may perform the function of the touch member. The touch layer TSL may include a plurality of sensing areas and a plurality of sensing electrodes.

Referring again to FIG. 5, the front stacked structure 200 may be arranged in front of the display panel 100. The front stacked structure 200 may include a polarizing member 230, a shock absorbing layer 220, and a cover window 210 sequentially stacked forward from the display panel 100.

The polarizing member 230 may polarize light that passes therethrough. The polarizing member 230 may reduce the reflection of external light. In one or more embodiments, the polarizing member 230 may be a polarizing film. The polarizing film may include a polarizing layer and protective substrates arranged on and under the polarizing layer. The polarizing layer may include a polyvinyl alcohol film. The polarizing layer may be stretched in a direction. The direction in which the polarizing layer is stretched may be an absorption axis, and a direction normal (e.g., perpendicular) to the above direction may be a transmission axis. The protective substrates may be arranged on a surface and the other surface of the polarizing layer, respectively. The protective substrates may be made of, but not limited to, cellulose resin, such as triacetyl cellulose, or polyester resin.

The shock absorbing layer 220 may be arranged in front of the polarizing member 230. The shock absorbing layer 220 may protect structures such as the display panel 100 thereunder from external shock. In an embodiment, the shock absorbing layer 220 may be a polymer film. The polymer film may include, for example, at least one of polyethylene terephthalate (PET), polyethylene naphthalate (PEN), polyether sulfone (PES), polyimide (PI), polyarylate (PAR), polycarbonate (PC), polymethyl methacrylate (PMMA), or cycloolefin copolymer (COC).

The cover window 210 may be arranged in front of the shock absorbing layer 220. The cover window 210 may protect the display panel 100. The cover window 210 may be made of a transparent material. The cover window 210 may include, for example, glass or plastic.

When the cover window 210 includes glass, the glass may be ultra-thin glass (UTG) or thin glass. The ultra-thin glass or the thin glass may have flexible characteristics so that it can be curved, bent, folded, or rolled. A thickness of the glass may be, for example, in the range of about 10 μm to about 300 μm. For example, glass having a thickness of about 10 μm to about 100 μm or a thickness of about 30 μm may be applied. The glass of the cover window 210 may include soda lime glass, alkali alumino silicate glass, borosilicate glass, or lithium alumina silicate glass. The glass of the cover window 210 may include chemically tempered or thermally tempered glass to have high strength. Chemical tempering may be achieved through an ion exchange process in alkaline salts. The ion exchange process may be performed two or more times. The cover window 210 may also be a polymer film coated with a thin layer of glass on both (e.g., simultaneously) sides (e.g., opposite sides).

When the cover window 210 includes plastic, it may better exhibit flexible characteristics such as folding. Examples of plastics applicable to the cover window 210 may include, but are not limited to, polyimide, polyacrylate, polymethylmethacrylate (PMMA), polycarbonate (PC), polyethylenenaphthalate (PEN), polyvinylidene chloride, polyvinylidene difluoride (PVDF), polystyrene, ethylene vinylalcohol copolymer, polyethersulphone (PES), polyetherimide (PEI), polyphenylene sulfide (PPS), polyallylate, tri-acetyl cellulose (TAC), and cellulose acetate propionate (CAP). The plastic cover window 210 may include one or more of the plastic materials listed above.

In one or more embodiments, the front stacked structure 200 may further include a front bonding member that bonds adjacent stacked members together. For example, the front bonding member may be arranged between the cover window 210 and the shock absorbing layer 220 and between the shock absorbing layer 220 and the polarizing member 230 to bond them together. The front bonding member may be a pressure sensitive adhesive.

The rear stacked structure 300 is arranged behind the display panel 100. The rear stacked structure 300 may include a protective member 310 and a cushion layer 320 sequentially stacked rearward (e.g., in a direction opposite to the direction in which the display panel 100 display a screen) from the display panel 100.

The protective member 310 may include a polymer film. The protective member 310 may be arranged under the display panel 100 to protect the display panel 100 from under the display panel 100. The protective member 310 will be described in more detail later.

The cushion layer 320 may be arranged under the protective member 310. The cushion layer 320 may prevent or reduce damage to the display panel 100 by absorbing external shock. The cushion layer 320 may be composed of a single layer or a plurality of stacked layers. For example, the cushion layer 320 may include an elastic material such as polyurethane or polyethylene resin. In one or more embodiments, the cushion layer 320 may be made of a foam material similar to sponge.

In one or more embodiments, the rear stacked structure 300 may further include a heat dissipation member. The heat dissipation member may be arranged behind the cushion layer 320. The heat dissipation member may dissipate heat generated from the display panel 100 or other components of the display device 10. In one or more embodiments, the heat dissipation member may include a first heat dissipation layer including graphite or carbon nanotubes and a second heat dissipation layer made of a metal thin layer such as copper, nickel, ferrite or silver that can shield electromagnetic waves and has excellent or suitable thermal conductivity.

In one or more embodiments, the rear stacked structure 300 may further include a rear bonding member that bonds adjacent stacked members together. For example, the rear bonding member may be arranged between the display panel 100 and the protective member 310 and between the protective member 310 and the cushion layer 320 to bond them together. The rear bonding member may be a pressure sensitive adhesive.

The protective member 310 of the display device 10 will now be described.

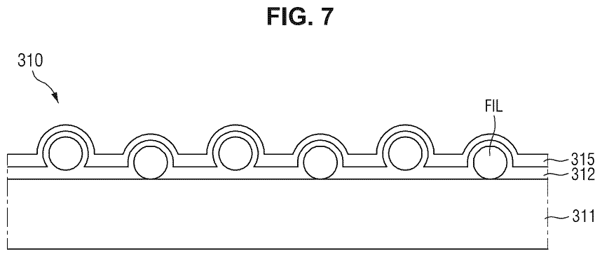

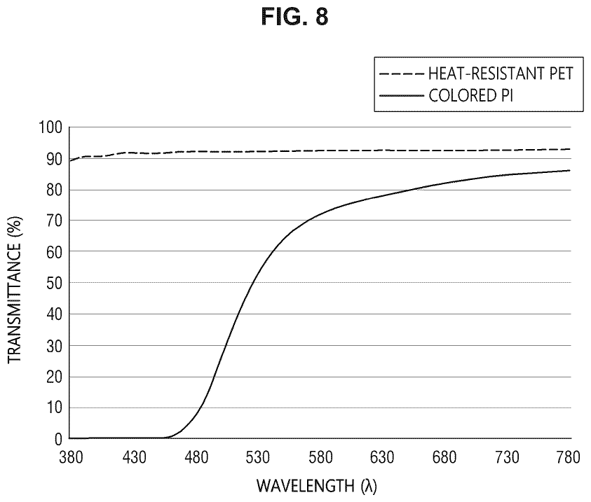

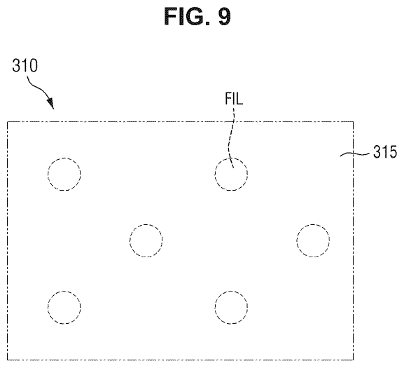

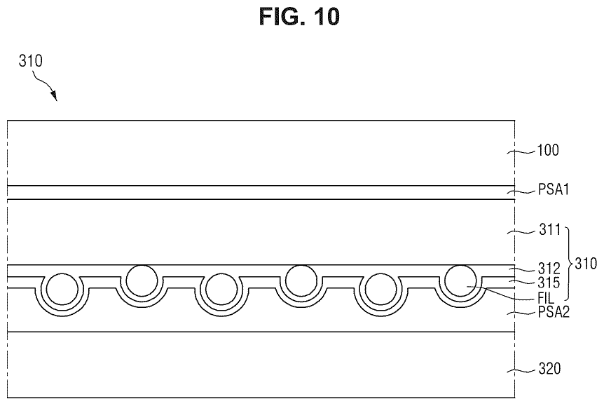

FIG. 7 is a schematic cross-sectional view of a protective member 310 according to one or more embodiments. FIG. 8 is a graph illustrating the transmittance of heat-resistant PET with respect to wavelength. FIG. 9 is a schematic plan view of the protective member 310 according to one or more embodiments. FIG. 10 is a schematic cross-sectional view of a portion of a display device 10 according to one or more embodiments.

Referring to FIG. 7, the protective member 310 according to the embodiment may include a base layer 311, a primer layer 312 arranged on the base layer 311, and an antistatic layer 315 arranged on the primer layer 312.

The base layer 311 may support the protective member 310. The base layer 311 may include a polymer film. The polymer film may include, for example, at least one of polyethylene terephthalate (PET), polyethylene naphthalate (PEN), polyether sulfone (PES), polyimide (PI), polyarylate (PAR), polycarbonate (PC), polymethyl methacrylate (PMMA), or cycloolefin copolymer (COC).

In one or more embodiments, the base layer 311 may be heat-resistant PET. The heat-resistant PET may be fabricated through post-thermal processing to improve the high-temperature deformation of general PET. When none heat-resistant or related art PET is thermally processed, oligomers present in the polymer move to the surface, causing an increase in haze. Accordingly, optical properties may deteriorate. The heat-resistant PET may be made to have relatively low haze and high transmittance (or transmissivity) by removing the oligomers through non-thermal treatment. In one or more embodiments, the heat-resistant PET may be made to have a relatively low heat shrinkage rate through thermal processing.

FIG. 8 illustrates the transmittance of heat-resistant PET and colored PI with respect to wavelength. As illustrated in FIG. 8, the heat-resistant PET may have a transmittance of about 90% or more in a visible light wavelength range. In one or more embodiments, as for other physical properties of the heat-resistant PET, the heat-resistant PET may have a haze of about 2% or less and a glass transition temperature of about 99° C. The heat-resistant PET may have a heat shrinkage rate of about 0.2% or less when exposed to about 150° C. for about 30 minutes.

In one or more embodiments, heat-resistant PET having excellent or suitable optical and heat-resistant properties may be utilized as the base layer 311. However, the present disclosure is not limited thereto.

A thickness of the base layer 311 may be about 10 μm to about 100 μm. In one or more embodiments, the thickness of the base layer 311 may be about 35 μm to about 75 μm. The base layer 311 having a thickness within the above range can secure the durability and folding characteristics of the protective member 310 when the display device 10 is folded/unfolded.

The primer layer 312 may be arranged on the base layer 311. The primer layer 312 may exhibit good or suitable adhesion to the antistatic layer 315 and the base layer 311 to bond them together.

The primer layer 312 may include a binder resin, for example, a heat or UV curable resin. Polyurethane resin, polyester resin, polyacrylic resin, and/or the like can be utilized as the binder resin.

The primer layer 312 may be applied on the base layer 311 utilizing a solution process such as coating, dipping or spraying and then may be dried or cured.

A thickness of the primer layer 312 may be about 10 nm to about 300 nm. In an embodiment, the thickness of the primer layer 312 may be about 35 nm to about 100 nm. The primer layer 312 having a thickness within the above range may exhibit excellent or suitable adhesion to the antistatic layer 315 and the base layer 311.

The primer layer 312 may include fillers FIL in addition to the binder resin. The fillers FIL may prevent or reduce reduction of the movability and dent defects of the protective member 310 during a fabrication process of the protective member 310. The fillers FIL may include barium sulfate, silica, or calcium carbonate. In one or more embodiments, the fillers FIL may be silica.

A particle size of the fillers FIL may be about 0.01 μm to about 2 μm. In one or more embodiments, the particle size of the fillers FIL may be about 0.1 μm to about 1 μm. The fillers FIL having a particle size within the above range may form (or provide) fine protrusions on the surface of the protective member 310, thereby preventing or reducing reduction of the movability and detent defects of the protective member 310.

The fillers FIL may be included in an amount of about 0.01% to about 80% by weight based on the total weight of 100% of the primer layer 312. In one or more embodiments, the fillers FIL may be included in an amount of about 0.1% to about 50% by weight based on the total weight of 100% of the primer layer 312. The fillers FIL included in the primer layer 312 in an amount within the above range can secure the processability of the primer layer 312 and reduce the surface friction coefficient of the protective member 310.

The fillers FIL may be covered with the primer layer 312 and dispersed within the primer layer 312. For example, the fillers FIL may be arranged inside the primer layer 312 without protruding out of the surface of the primer layer 312. The binder resin of the primer layer 312 may cover the entire surfaces of the fillers FIL. Accordingly, the surface of the primer layer 312 may have protrusions formed in areas overlapping the fillers FIL and recesses formed in areas not overlapping the fillers FIL. For example, the surface of the primer layer 312 may have irregularities.

Some of the fillers FIL may contact the surface of the base layer 311, and the other fillers FIL may be spaced apart from the surface of the base layer 311. However, the present disclosure is not limited thereto, and all of the fillers FIL may contact the surface of the base layer 311, or all of the fillers FIL may not contact the surface of the base layer 311.

The antistatic layer 315 may be arranged on the primer layer 312. The antistatic layer 315 can prevent or reduce static electricity from being generated within the protective member 310. The antistatic layer 315 may be formed to be uneven along the irregularities of the primer layer 312.

The antistatic layer 315 may include a binder resin and an antistatic agent.

The binder resin of the antistatic layer 315 may be water-soluble or water-insoluble (organic solvent type or kind). For example, a polymer compound having one or more functional groups selected from among an acrylic group, a urethane group, an epoxy group, an amide group, a hydroxyl group, and a silane group may be utilized alone, or two or more polymer compounds may be utilized in combination. For example, the binder resin may utilize, but is not limited to, one or more of acrylic resin, polyurethane, polyepoxy, polyamide, polyester, ethyl vinyl acetate, polysiloxane, and copolymers thereof.

The antistatic agent is not particularly limited as long as it has antistatic properties. However, the antistatic agent may utilize, for example, one or more of a conductive polymer, metal salt with metal ions, an ionic liquid, a carbon material, and a surfactant.

The conductive polymer may utilize one or more of polyethylene dioxythiophene (PEDOT), polyacetylene, poly(p-phenylene vinylene), poly(p-phenylene), poly(thienylene vinylene), polythiophene, polyaniline, polyisothianaphthene, polypyrrole, and poly(p-phenylene sulfide).

Examples of the metal salt may include lithium salt, lithium imide, lithium amide, and potassium salt. Examples of the ionic liquid may include pyridine imide. The carbon material may be, for example, one or more of carbon black, graphite, graphene, carbon nanotube (CNT), and carbon nanofiber (CNF). Examples of the surfactant may include sulfonate, quaternary ammonium salt, and lauryl dimethylbenzyl ammonium salt.

The antistatic layer 315 may be coated through a solution process such as gravure coating, comma knife coating, roll coating or spray coating, but the present disclosure is not limited thereto.

A thickness of the antistatic layer 315 may be about 10 nm to about 1000 nm. In one or more embodiments, the thickness of the antistatic layer 315 may be about 80 nm to about 200 nm. The antistatic layer 315 having a thickness within the above range can secure coatability and improve antistatic properties.

The thickness of the antistatic layer 315 may be smaller than the particle size of the fillers FIL. For example, a lowermost surface of the antistatic layer 315 may be located lower than an uppermost portion of each filler FIL. The lowermost surface of the antistatic layer 315 may be arranged closer to an upper surface of the base layer 311 than the uppermost portion of each filler FIL may be arranged to the upper surface of the base layer 315.

As described above, the protective member 310 may include the base layer 311, the primer layer 312, and the antistatic layer 315.

In one or more embodiments, the thicknesses of the primer layer 312 and the antistatic layer 315 may be smaller than the particle size of the fillers FIL so that irregularities can be formed on the surface of the protective member 310. The thickness of the primer layer 312 may be smaller than the particle size of the fillers FIL, and the thickness of the antistatic layer 315 may be smaller than the particle size of the fillers FIL. In one or more embodiments, the sum of the thickness of the primer layer 312 and the thickness of the antistatic layer 315 may be smaller than the particle size of the fillers FIL. Accordingly, even if the primer layer 312 and the antistatic layer 315 cover the fillers FIL, irregularities may be formed on the surface of the protective member 310 because the particle size of the fillers FIL is greater than the sum of the thickness of the primer layer 312 and the thickness of the antistatic layer 315.

In the protective member 310, the fillers FIL may be dispersed within the primer layer 312 to reduce the surface friction coefficient of the protective member 310. In this case, a ratio of an area occupied by the fillers FIL to the total area of the protective member 310 may be about 1.5% to about 2%. When the ratio of the area occupied by the fillers FIL to the total area of the protective member 310 is within the above range, the surface friction coefficient of the protective member 310 can be reduced while the fabricability of the protective member 310 is secured.

Because irregularities are formed on the surface of the protective member 310 due to the fillers FIL included in the primer layer 312, the surface friction coefficient of the protective member 310 can be reduced. In one or more embodiments, the surface friction coefficient of the protective member 310 may be about 0.320 to about 0.451. Here, the surface of the protective member 310 refers to the surface of the antistatic layer 315. The protective member 310 having a surface friction coefficient within the above range can be improved in movability during the fabrication process of the protective member 310.

For example, the protective member 310 may be attached to a lower surface of a display panel 100. The protective member 310 and the display panel 100 may be attached to each other through an alignment process. In the process of moving and aligning the protective member 310 while the display panel 100 is fixed, if the surface friction coefficient of the protective member 310 is small, the degree to which the protective member 310 is moved well, that is, movability is improved. Thus, the alignment process can be easily performed. Therefore, in the current embodiment, the protective member 310 may be formed to have a surface friction coefficient of about 0.320 to about 0.451. Accordingly, the movability of the protective member 310 can be improved, thus facilitating the alignment process of the protective member 310 with the display panel 100.

Referring to FIG. 10, the protective member 310 described above may be arranged under the display panel 100, and a cushion layer 320 may be arranged under the protective member 310. A first bonding member PSA1 may be arranged between the protective member 310 and the display panel 100 to bond the protective member 310 and the display panel 100 together. A second bonding member PSA2 may be arranged between the protective member 310 and the cushion layer 320 to bond the protective member 310 and the cushion layer 320 together.

The protective member 310 structured as illustrated in FIG. 7 may be inverted and then bonded to the display panel 100. For example, the base layer 311 of the protective member 310 may be placed to face the lower surface of the display panel 100, and the antistatic layer 315 of the protective member 310 may be placed to face the cushion layer 320. The first bonding member PSA1 may contact the lower surface of the display panel 100 and the base layer 311 of the protective member 310 to bond them together. The second bonding member PSA2 may contact the antistatic layer 315 of the protective member 310 and the cushion layer 320 to bond them together.

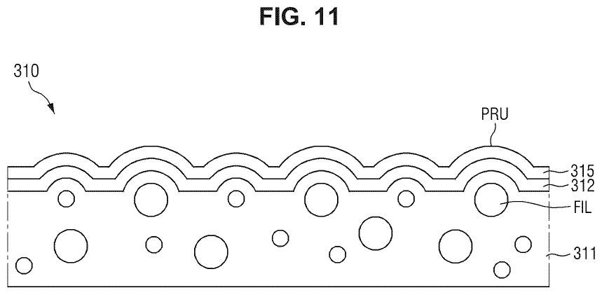

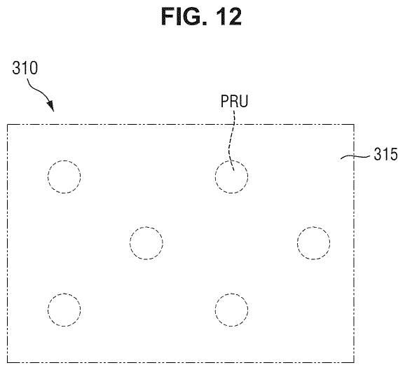

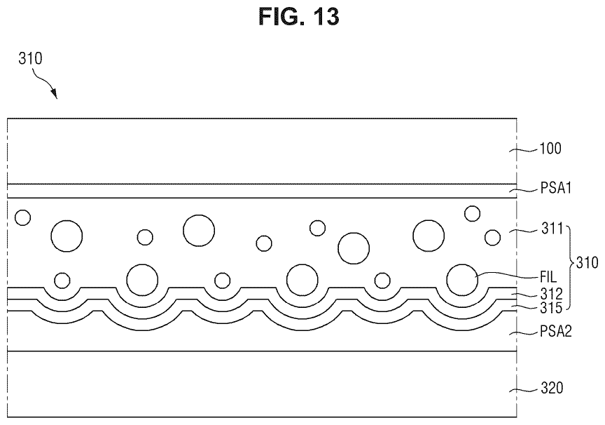

FIG. 11 is a schematic cross-sectional view of a protective member 310 according to one or more embodiments. FIG. 12 is a schematic plan view of the protective member 310 according to one or more embodiments. FIG. 13 is a schematic cross-sectional view of a portion of a display device according to one or more embodiments.

Referring to FIGS. 11 through 13, the current embodiment is different from the embodiment of FIGS. 7 through 10 described above in that a base layer 311 includes fillers FIL. Therefore, the same elements as those of the above-described embodiment will be briefly described, and differences will be mainly described below.

The protective member 310 according to the embodiment may include the base layer 311, a primer layer 312 arranged on the base layer 311, and an antistatic layer 315 arranged on the primer layer 312.

The base layer 311 may support the protective member 310. The base layer 311 may include a polymer film. The polymer film may include, for example, at least one of polyethylene terephthalate (PET), polyethylene naphthalate (PEN), polyether sulfone (PES), polyimide (PI), polyarylate (PAR), polycarbonate (PC), polymethyl methacrylate (PMMA), or cycloolefin copolymer (COC). In one or more embodiments, the base layer 311 may be general PET.

The base layer 311 may include the fillers FIL. The fillers FIL may prevent or reduce a reduction of the movability and dent defects of the protective member 310 during a fabrication process of the protective member 310. The fillers FIL may include barium sulfate, silica, or calcium carbonate. In one or more embodiments, the fillers FIL may be silica.

A particle size of the fillers FIL may be about 0.01 μm to about 2 μm. In one or more embodiments, the particle size of the fillers FIL may be about 0.1 μm to about 1 μm. The fillers FIL having a particle size within the above range may form (or provide) fine protrusions on the surface of the protective member 310, thereby preventing or reducing a reduction of the movability and detent defects of the protective member 310.

The fillers FIL may be included in an amount of about 0.01% to about 80% by weight based on the total weight of 100% of the base layer 311. In one or more embodiments, the fillers FIL may be included in an amount of about 0.1% to about 50% by weight based on the total weight of 100% of the base layer 311. The fillers FIL included in the base layer 311 in an amount within the above range can secure the processability of the base layer 311 and reduce the surface friction coefficient of the protective member 310.

The fillers FIL may be dispersed within the base layer 311. For example, the fillers FIL may be arranged inside the base layer 311 without protruding out of the surface of the base layer 311. In one or more embodiments, a resin of the base layer 311 may cover the entire surfaces of the fillers FIL. Accordingly, the surface of the base layer 311 may have protrusions formed in areas overlapping the fillers FIL and recesses formed in areas not overlapping the fillers FIL. For example, the surface of the base layer 311 may have irregularities.

The primer layer 312 may be arranged on the base layer 311. The primer layer 312 may exhibit good or suitable adhesion to the antistatic layer 315 and the base layer 311 to bond them together.

A thickness of the primer layer 312 may be within the thickness range described in FIG. 7. For example, the thickness of the primer layer 312 may be about 10 nm to about 300 nm. The primer layer 312 having a thickness within the above range may exhibit excellent or suitable adhesion to the antistatic layer 315 and the base layer 311, and the irregularities formed on the base layer 311 may be formed on the surface of the primer layer 312.

The surface of the primer layer 312 may have irregularities corresponding to the irregularities of the base layer 311 formed by the fillers FIL. Accordingly, the surface of the primer layer 312 may have protrusions formed in areas overlapping the fillers FIL and recesses formed in areas not overlapping the fillers FIL.

The antistatic layer 315 may be arranged on the primer layer 312. The antistatic layer 315 can prevent or reduce static electricity from being generated within the protective member 310. The antistatic layer 315 may have protrusions PRU formed along the irregularities of the primer layer 312.

The protrusions PRU may be arranged on the surface of the antistatic layer 315 and may be spaced apart from each other. In one or more embodiments, the protrusions PRU may be randomly arranged. In one or more embodiments, the protective member 310 may include the protrusions PRU arranged on the surface, for example, on the surface of the antistatic layer 315. The protrusions PRU may be formed by the irregularities of the base layer 311 formed by the fillers FIL and the irregularities of the primer layer 312 formed to cover the irregularities of the base layer 311. Accordingly, the protrusions PRU may overlap the fillers FIL of the base layer 311, and areas other than the protrusions PRU may not overlap the fillers FIL.

The surface friction coefficient of the protective member 310 may be reduced by the protrusions PRU formed on the surface. In this case, a ratio of an area occupied by the fillers FIL to the total area of the protective member 310 may be about 1.5% to about 2%. When the ratio of the area occupied by the fillers FIL to the total area of the protective member 310 is within the above range, the surface friction coefficient of the protective member 310 can be reduced while the fabricability of the protective member 310 is secured.

The surface friction coefficient of the protective member 310 may be about 0.320 to about 0.451. Here, the surface of the protective member 310 refers to the surface of the antistatic layer 315. The protective member 310 having a surface friction coefficient within the above range can be improved in movability during the fabrication process of the protective member 310.

Referring to FIG. 13, the protective member 310 described above may be arranged under a display panel 100, and a cushion layer 320 may be arranged under the protective member 310. A first bonding member PSA1 may be arranged between the protective member 310 and the display panel 100 to bond the protective member 310 and the display panel 100 together. A second bonding member PSA2 may be arranged between the protective member 310 and the cushion layer 320 to bond the protective member 310 and the cushion layer 320 together.

The protective member 310 structured as illustrated in FIG. 11 may be inverted and then bonded to the display panel 100. For example, the base layer 311 of the protective member 310 may be placed to face a lower surface of the display panel 100, and the antistatic layer 315 of the protective member 310 may be placed to face the cushion layer 320. The first bonding member PSA1 may contact the lower surface of the display panel 100 and the base layer 311 of the protective member 310 to bond them together. The second bonding member PSA2 may contact the antistatic layer 315 of the protective member 310 and the cushion layer 320 to bond them together.

Hereinafter, experiments on the protective members 310 according to the above-described embodiments will be described.

### Preparation of Protective Member Samples

### Comparative Example

A primer layer was applied to a thickness of 50 nm on heat-resistant PET having a thickness of 50 μm. The primer layer was formed by mixing about 10% by weight of silica particles having a particle size of about 300 nm with polyester resin (e.g., 90% by weight). An antistatic layer was formed to a thickness of about 600 nm on the primer layer. The antistatic layer was formed by mixing about 10% by weight of silica particles having a particle size of about 2 μm with polyurethane resin mixed with an antistatic agent (e.g., 90% by weight).

### EXAMPLE

A protective member according to Example was fabricated under the same conditions as Comparative Example except that an antistatic layer having a thickness of 100 nm but not including silica particles was formed.

### Experimental Example 1: Measurement of Surface Friction Coefficients of Protective Members

The surface friction coefficients of seventeen protective member samples fabricated according to Comparative Example and Example were measured. Here, the surface refers to the surface of an antistatic layer of a protective member. The surface friction coefficients were measured utilizing Bruker's universal mechanical tester (UMT), and the measurement conditions were a load of 5N, a speed of about 300 mm/min, a reciprocation of about 40 mm, and a duration of about 80 seconds.

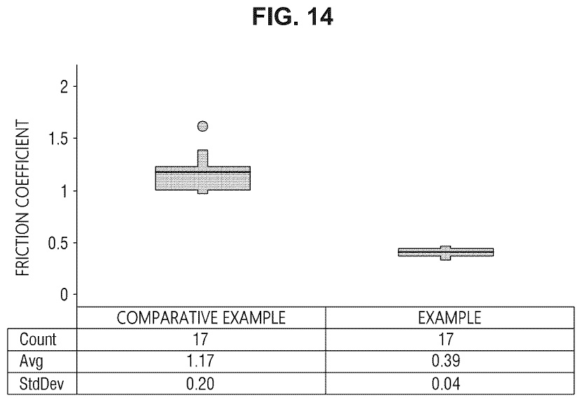

The results are shown in Table 1 and FIG. 14. Table 1 shows the results of measuring the surface friction coefficients of the protective member samples of Comparative Example and Example. FIG. 14 is a graph illustrating the surface friction coefficients of Comparative Example and Example according to Experimental Example 1.

TABLE 1

Surface Friction Coefficient

| | Comparative | |
|---|---|---|
| # | Example | Example |
| 1 | 0.959 | 0.444 |
| 2 | 0.988 | 0.431 |
| 3 | 1.039 | 0.439 |
| 4 | 1.263 | 0.357 |
| 5 | 1.131 | 0.355 |
| 6 | 1.225 | 0.366 |
| 7 | 1.002 | 0.454 |
| 8 | 1.126 | 0.412 |
| 9 | 1.203 | 0.451 |
| 10 | 1.384 | 0.392 |
| 11 | 1.607 | 0.392 |
| 12 | 1.224 | 0.371 |
| 13 | 0.959 | 0.337 |
| 14 | 0.988 | 0.360 |
| 15 | 1.039 | 0.362 |
| 16 | 1.607 | 0.320 |
| 17 | 1.224 | 0.331 |

Referring to Table 1 and FIG. 14, an average value of the surface friction coefficients of the protective member samples according to Comparative Example was about 1.17, and an average value of the surface friction coefficients of the protective member samples according to Example was about 0.39.

As is apparent from these results, the surface friction coefficient of the protective member according to Example was significantly reduced, in a range of about 0.320 to about 0.454.

### Experimental Example 2: Measurement of Surface Quality of Protective Members

Surface quality (Kc) values of eighteen protective member samples fabricated according to Comparative Example and Example were measured. A measuring instrument utilized was RHOPOINT Instruments' Optimap. A Kc value is a value obtained by quantifying surface quality and a value measured utilizing Optimap. The more uneven a measured surface is due to texture, flatness, number of defects, size, shape, and/or the like, the greater the Kc value. The more even the surface, the smaller the Kc value.

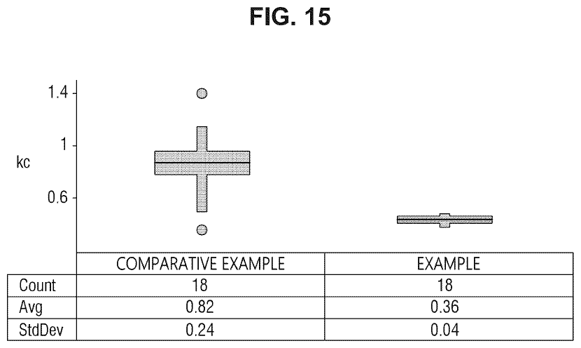

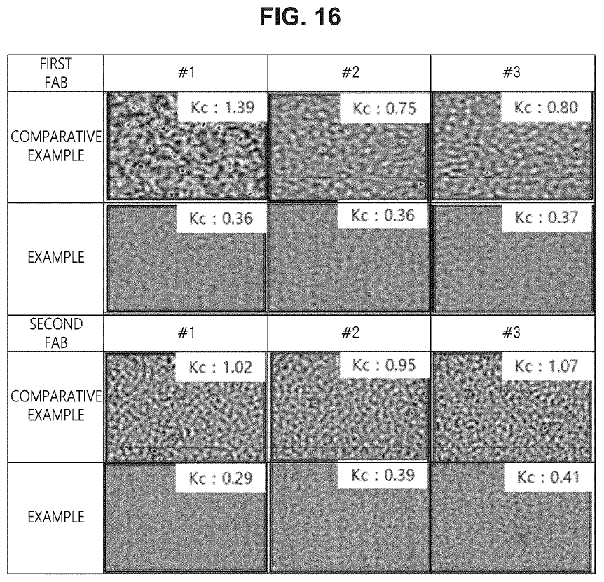

The results are shown in FIGS. 15 and 16. FIG. 15 is a graph illustrating the Kc values of the protective member samples according to Experimental Example 2. FIG. 16 is a table showing Optimap images of the protective member samples according to Experimental Example 2.

Referring to FIGS. 15 and 16, an average Kc value of the protective member samples according to Comparative Example was about 0.82, and an average Kc value of the protective member samples according to Example was about 0.36.

As is apparent from these results, the surface quality of the protective member according to Example was improved.

### Experimental Example 3: Inspection of Defect Rate of Protective Members

Each of the protective members according to Comparative Example and Example was attached to a display panel and then inspected for dent defects and foreign matter defects utilizing Optimap. The results are shown in Table 2. In Table 2, quantity refers to the number of display panels to which the protective members are attached, and first through third rounds refer to inspection rounds (here, different display panels were inspected in the first through third rounds). In one or more embodiments, improvement aspect refers to an improvement rate of Example compared to Comparative Example.

TABLE 2

| | | Comparative Example | | Example | | Improvement |
|---|---|---|---|---|---|---|
| | | Defect | Number of | Defect | Number of | Effect |
| | | Rate (%) | Defective | Rate (%) | Defective | (%) |
| 1^{st} round | Quantity | 262,350 | | 6,615 | | |
| | Dent | 0.46 | 1207 | 0.09 | 6 | 80 |
| | Foreign | 0.51 | 1338 | 0.21 | 14 | 59 |
| | matter | | | | | |
| 2^{nd} round | Quantity | 314,640 | | 28,485 | | |
| | Dent | 1.14 | 3587 | 0.37 | 105 | 68 |
| | Foreign | 0.59 | 1856 | 0.47 | 134 | 20 |
| | matter | | | | | |
| 3^{rd} round | Quantity | 50,850 | | 48,510 | | |
| | Dent | 0.65 | 331 | 0.36 | 176 | 44 |
| | Foreign | 0.28 | 144 | 0.36 | 177 | −29 |
| | matter | | | | | |
| Total | Quantity | 627,840 | | 83,610 | | |
| | Dent | 0.82 | 5125 | 0.34 | 287 | 58 |
| | Foreign | 0.53 | 3338 | 0.39 | 325 | 27 |
| | matter | | | | | |

Referring to Table 2, the protective member according to Example was improved in dent defects by about 58% and improved in foreign matter by about 27% compared to the protective member according to Comparative Example.

As is apparent from these results, the protective member according to Example can be improved in dent defects and in foreign matter defects.

In a display device according to one or more embodiments, the defects and surface quality of a protective member attached to a lower surface of the display panel can be improved by reducing the surface friction coefficient of the protective member.

The light-emitting device, the display device, the electronic apparatus, the electronic equipment, or any other relevant devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

In concluding the detailed description, those skilled in the art will appreciate that many variations and modifications can be made to the embodiments without substantially departing from the principles of the present disclosure. Therefore, the disclosed embodiments of the present disclosure are utilized in a generic and descriptive sense only and not for purposes of limitation.

What is claimed is:

1. A display device comprising:
a display panel; and
a protective member on a surface of the display panel,
wherein the protective member comprises:
a base layer;
a primer layer on the base layer and comprising fillers; and
an antistatic layer on the primer layer,
wherein a thickness of the antistatic layer is smaller than a particle size of the fillers.

2. The display device of claim 1, wherein the base layer is closer to the display panel than the antistatic layer is to the display panel.

3. The display device of claim 1, wherein the base layer comprises polyethylene terephthalate (PET) and has a heat shrinkage rate of about 0.2% or less when exposed to a temperature of about 150° C. for about 30 minutes.

4. The display device of claim 1, wherein a thickness of the base layer is about 10 micrometer (μm) to about 100 μm.

5. The display device of claim 1, wherein the particle size of the fillers is about 0.01 micrometer (μm) to about 2 μm.

6. The display device of claim 1, wherein content of the fillers is about 0.01% to about 80% by weight based on total weight of 100% of the primer layer.

7. The display device of claim 1, wherein a thickness of the primer layer is about 10 nanometer (nm) to about 300 nm.

8. The display device of claim 1, wherein the thickness of the antistatic layer is about 10 nanometer (nm) to about 1000 nm.

9. The display device of claim 1, wherein a sum of a thickness of the primer layer and the thickness of the antistatic layer is smaller than the particle size of the fillers.

10. The display device of claim 1, wherein a surface friction coefficient of the protective member is about 0.320 to about 0.451.

11. The display device of claim 1, further comprising:
a polarizing member on the display panel;
a shock absorbing layer on the polarizing member;
a cover window on the shock absorbing layer; and
bonding members between the display panel and the polarizing member, between the polarizing member and the shock absorbing layer, and between the shock absorbing layer and the cover window.

12. The display device of claim 11, further comprising a cushion layer on a surface of the protective member,
wherein the cushion layer faces the antistatic layer.

13. A display device comprising:
a display panel; and
a protective member on a surface of the display panel,
wherein the protective member comprises:
a base layer comprising fillers;
a primer layer on the base layer; and
an antistatic layer on the primer layer and having protrusions, and
wherein the protrusions overlap the fillers.

14. The display device of claim 13, wherein a ratio of an area occupied by the fillers to a total area of the protective member is about 1.5% to about 2%.

15. The display device of claim 13, wherein a surface friction coefficient of the protective member is about 0.320 to about 0.451.

16. The display device of claim 13, wherein a thickness of the base layer is about 10 micrometer (μm) to about 100 μm.

17. The display device of claim 13, wherein content of the fillers is about 0.01% to about 80% by weight based on total weight of 100% of the base layer.

18. The display device of claim 13, wherein a thickness of the primer layer is about 10 nanometer (nm) to about 300 nm.

19. The display device of claim 13, wherein a thickness of the antistatic layer is about 10 nanometer (nm) to about 1000 nm.

20. A display device comprising:
a display panel;
a polarizing member on a surface of the display panel;
a shock absorbing layer on the polarizing member;
a cover window on the shock absorbing layer; and
a protective member on an opposite surface of the display panel,
wherein the protective member comprises:
a base layer;
a primer layer on the base layer and comprising fillers; and
an antistatic layer on the primer layer,
wherein a sum of a thickness of the primer layer and a thickness of the antistatic layer is smaller than a particle size of the fillers.
